(19) United States
(12) Patent Application Publication
(10) Pub. No.: US 2025/0305134 A1
(43) Pub. Date: Oct. 2, 2025

(54) CAPACITIVELY COUPLED PLASMA-ENHANCED ATOMIC LAYER DEPOSITION METHOD

(71) Applicants: UNIVERSITE GRENOBLE ALPES, Saint Martin D'Heres (FR); CENTRE NATIONAL DE LA RECHERCHE SCIENTIFIQUE, Paris (FR)

(72) Inventors: Marceline BONVALOT, Saint Ismier (FR); Thierry CHEVOLLEAU, Saint Egreve (FR); Moustapha JAFFAL, Grenoble (FR)

(21) Appl. No.: 18/866,108

(22) PCT Filed: May 15, 2023
(86) PCT No.: PCT/EP2023/062989

§ 371 Date: Nov. 15, 2024

(30) Foreign Application Priority Data
May 17, 2022 (FR) 2204649

(51) Int. Cl. C23C 16/455; C23C 16/458; C23C 16/505

(52) U.S. Cl. CPC C23C 16/45538; C23C 16/45553; C23C 16/4582; C23C 16/505

(57) ABSTRACT

A plasma-enhanced atomic layer deposition method and the associated reactor, the method including a supply of a substrate into a plasma reactor including a reaction chamber, and a plurality of atomic layer deposition cycles on the exposed surface of the substrate, including an injection in the reaction chamber of a precursor based on a first species, a plasma treatment of the exposed surface of the substrate by a plasma by capacity coupling between the plate and the lateral wall of the reaction chamber, by applying a radiofrequency power to the plate. Capacitive coupling makes it possible to create a plasma localised in the vicinity of the substrate, at low and finely adjustable ion energy and density.

### TECHNICAL FIELD OF THE INVENTION

The present invention relates to the field of plasma-enhanced atomic layer deposition methods. It is particularly advantageously applicable in the field of thin layer deposition, and more particularly of thin layers of controlled thickness, for example for microelectronic device manufacture.

### PRIOR ART

Atomic layer deposition (commonly referred to as ALD deposition) methods are routinely used to deposit thin layers, for example with thicknesses less than or equal to 100 nm, on 2D or 3D substrates. As a general rule, ALD deposition is a cyclical method comprising two main steps:
an injection of a precursor, typically a metallic precursor,
an injection of another precursor, typically a reagent such as a reagent based on oxygen or nitrogen.

These steps are self-limiting, which makes it possible to deposit conformal and uniform layers on the substrate. The energy required for the precursor reaction may typically be supplied by temperature (this is referred to as thermal ALD). This energy may be supplied using plasma enhancement (commonly referred to as PEALD, standing for Plasma-Enhanced ALD) to improve the surface reactivity. This makes it possible to lower the working temperature, typically to temperatures less than or equal to 250° C.

Plasma-enhanced ALD methods have been used to deposit numerous materials which remain difficult to deposit with thermal ALD. For some depositions, thermal ALD methods may not be reactive enough and/or require complex organic precursors.

Conventionally, PEALD methods use capacitively coupled or inductively coupled plasmas (commonly referred to as CCP, and ICP, respectively). For this, these methods are carried out in reactors generally comprising a reaction chamber 10′, a gaseous precursor intake 12′ configured to convey gaseous precursors into the chamber 10′, and a pumping module 13′ of the chamber 10′. In a conventional CCP reactor 1′, for example illustrated in FIG. 1A, the plasma is typically generated 3 at pressures of the order of a few Torr between two electrodes 110′, 18′ with a radiofrequency (RF) power device 16′. The electrodes 110′, 18′ are disposed parallel facing each other and the substrate is deposited between them, an electrode 110′ being the plate connected to the ground 110′ carrying the substrate 2. In conventional CCP techniques, the ion bombardment on the plate is however substantial. Gates may be added in the inter-electrode gap to limit this ion bombardment.

In an ICP reactor 1′, for example illustrated in FIG. 1B, the plasma is generated 3, typically at pressures of the order of 100 mTorr and in an offset manner, by an induction source 15′ with an RF power device 16′, then is conveyed into the reaction chamber 10′ to the substrate 2 by scattering. Ion bombardment is thus limited.

Indeed, ion bombardment may generate isolated or extensive defects, such as implantations, displacements of atoms, compressive stress in the growth layer, or its sputtering.

However, ion bombardment may be beneficial to modulate the surface reactivity and improve deposition properties such as density, morphology, stress, conformity in particular on a 3D substrate, on condition that the energy of this bombardment and its ion density are controlled.

For this purpose, some recently developed methods use ICP plasmas to which an additional RF polarisation has been added at the substrate-holder, to allow the extraction of ions from the remote plasma with a controlled incident energy when they arrive in the vicinity of the substrate.

In practice, materials prepared in these reactors are above all oxides or nitrides, the physicochemical properties of which can optionally be modulated by an additional polarisation for extracting ions from the plasma so that they enhance the growth mechanisms. Obtaining other materials remains limited.

Poorly controlled ion bombardment may furthermore affect the sought properties of the deposited layer, and the substrate may be damaged by ion bombardment.

Hence, an object of the present invention is to provide an improved plasma-enhanced deposition solution. A non-limiting aim of the invention may be that of providing an improved plasma-enhanced atomic layer deposition method, in particular in terms of the deposited layer and/or deposition selectivity.

The other objects, features and advantages of the present invention will become apparent upon examining the following description and the appended drawings. It should be understood that other advantages could be incorporated.

### SUMMARY OF THE INVENTION

To achieve this aim, according to an aspect, a plasma-enhanced atomic layer deposition method is provided, comprising:
a supply of a substrate having an exposed surface in a plasma reactor, the plasma reactor comprising a reaction chamber delimited by walls and an electrically conductive plate. The electrically conductive plate has an upper face whereon the substrate is disposed. A lateral wall of the reaction chamber is at least partly non-parallel with the upper face of the plate and electrically conductive.
a plurality of atomic layer deposition cycles on the exposed surface of the substrate, each cycle comprising:
   an injection into the reaction chamber of a precursor based on a first species,
   a plasma treatment of the exposed surface of the substrate with a plasma generated by capacitive coupling between the plate and the lateral wall, by applying a radiofrequency power to the plate.

Thanks to the non-parallel configuration of the two electrodes, capacitive coupling between the plate and the walls of the chamber makes it possible to create a plasma localised in the vicinity of the substrate, at low and finely adjustable ion energy and density, in particular relative to a conventional CCP reactor. These parameters may be adjusted according to the RF power and pressure conditions. This thus greatly limits damage to the substrate caused by ion bombardment. This weaker ion flow is furthermore more finely controllable relative to an ICP reactor with substrate polarisation, which makes it possible to arrive at a better compromise between the damage caused to the substrate and ion bombardment efficiency. This thus greatly limits damage to the substrate relative to the CCP reactor and to the ICP reactor with substrate polarisation.

Furthermore, this allows access to plasma parameters allowing depositions of different chemistry and microstructure, as will be apparent on reading the description.

According to a second aspect, a plasma-enhanced deposition reactor is provided, comprising:
a reaction chamber delimited by walls and comprising an electrically conductive plate having an upper face intended to receive a substrate,
a gaseous precursor intake configured to convey gaseous precursors into the reaction chamber,
a pumping module of the reaction chamber,
a power source configured to apply a radiofrequency power to the plate.

A lateral wall of the reaction chamber is at least partly non-parallel with the upper face of the plate and is electrically conductive. The upper face of the plate and the lateral wall are separated by a distance configured so as to generate a capacitively coupled plasma between the plate and the lateral wall.

The radiofrequency power applied to the plate and the distance between the plate and the lateral wall make it possible to generate the capacitively coupled plasma between these two elements. The plasma is thus generated in a localised manner in the vicinity of the substrate, thanks to the non-parallel configuration of the two electrodes, which has the advantages described above. Finally, this reactor allows depositions of layers of more varied chemical and microstructures than a conventional ICP reactor with or without substrate polarisation.

### BRIEF DESCRIPTION OF THE FIGURES

The aims, objects, as well as the features and advantages of the invention will become more apparent from the detailed description of an embodiment of the latter which is illustrated by the following appended drawings, wherein:

FIG. 1A shows a sectional view of a CCP reactor according to an example of the prior art.

FIG. 1B shows a sectional view of an ICP reactor according to an example of the prior art.

FIG. 2 shows a diagram of the deposition method, according to an embodiment example.

FIGS. 3A to 3E show a diagram of a metallic layer deposition cycle, according to several embodiment examples.

FIGS. 4A to 4C show a diagram of an oxide, nitride and/or sulphide layer deposition cycle, according to several embodiment examples.

FIG. 5 shows a sectional view of the plasma reactor according to an embodiment example, wherein the lateral wall is of conical geometry.

FIG. 6 shows a sectional view of the plasma reactor according to another embodiment example, wherein the lateral wall is of conical geometry.

FIG. 7 shows a sectional view of the plasma reactor according to another embodiment example, coupled with an ICP source.

FIG. 8 shows a sectional view of the plasma reactor illustrated in FIG. 5, equipped with an ellipsometer.

FIGS. 9A to 9D and 10A to 10C show flow graphs of ions generated by the plasma according to the plasma parameters, at constant power and pressure, respectively.

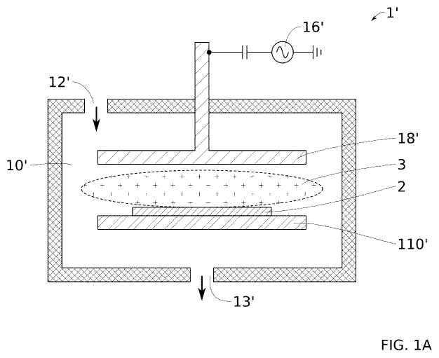

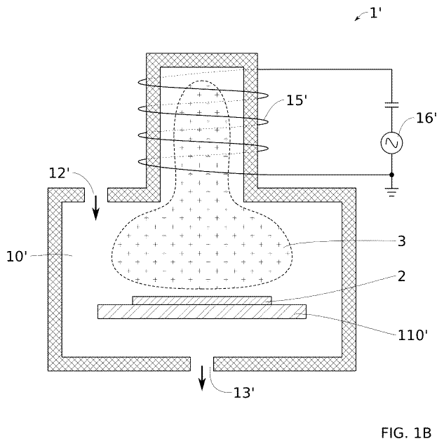

The drawings are given as examples and do not limit the invention. They form schematic representations of principle intended to facilitate understanding of the invention and are not necessarily plotted to the scale of practical applications. In particular, the relative dimensions of the substrate, the deposited layers and the reactor are not representative of reality.

### DETAILED DESCRIPTION OF THE INVENTION

Before starting a detailed review of embodiments of the invention, optional features of the method and the plasma reactor are set out hereinafter, which could possibly be used in combination or alternatively.

According to one example, the plate is polarised to the ground.

According to one example, the plurality of deposition cycles further comprises an injection into the reaction chamber of a precursor based on a second species.

According to one example, the plasma treatment is performed simultaneously with at least one injection into the reaction chamber of a precursor or following at least one injection into the reaction chamber of a precursor. This makes it possible to modulate the surface reactions during an injection or between two injections. This modulation is particularly enabled thanks to the low-density plasma generated.

According to one example, the radiofrequency polarisation power may be less than or equal to 80 W. The pressure in the reaction chamber may be less than or equal to 80 m Torr. The plasma treatment duration during a deposition cycle may be less than or equal to 1 minute. During the development of the invention, it was demonstrated that these parameters make it possible to activate and/or modify the surface reactivity between the precursor injections. These plasma conditions can advantageously modify the properties of the deposited material.

According to one example, the radiofrequency polarisation power may be greater than or equal to 50 W. The pressure in the reaction chamber may be less than or equal to 20 mTorr. The plasma treatment duration during a deposition cycle is greater than or equal to 1 minute. During the development of the invention, it was demonstrated that these parameters make it possible to remove, or sputter the precursor chemisorbed on the surface. These plasma conditions may be useful for selective depositions on 3D substrates.

According to one example, when the plasma is generated, the plasma treatment comprises the injection into the reaction chamber of a rare gas, also referred to as inert gas, preferably argon, optionally in a mixture with H₂. A so-called argon-based “inert” plasma is low-energy relative to other species. Synergistically with the low-density capacitive plasma generated, this makes it possible to modulate surface reactions by minimising the risk of damaging the exposed surface of the substrate.

According to one example, the plasma treatment being performed simultaneously with and/or after the injection of the precursor based on the first species, the first species is based on a metal. The plasma treatment thus makes it possible to remove the ligand from the metallic precursor and therefore metal-on-metal adsorption, by creating pendant bonds when the plasma is generated from an inert gas, for example argon, or reducing agent, for example H₂.

According to one example, the plasma treatment being performed between the injection of the precursor based on the first species and the injection of the precursor based on the second species and/or simultaneously with at least one of said injections, the first species is based on a metal and the second species is based on a metal.

According to one example, when the plasma is generated, the plasma treatment is free from dihydrogen injection. During the development of the invention, it was indeed demonstrated that the method requires no reduction of the growth layer by dihydrogen.

Preferably when the first species is a metal, the radiofrequency polarisation power may be less than or equal to 80 W. The pressure in the reaction chamber may be less than or equal to 80 mTorr. The plasma treatment duration during a deposition cycle may be less than or equal to 1 minute. The dose supplied by the ion bombardment makes it possible to remove and/or modify the ligands of the precursor to promote the deposition of a metallic layer. The deposited dose is limited, which improves the removal of the ligand further without risking removing the deposited metal.

According to one example, the metal has an electronegativity between 1.1 and 2.4.

Preferably, the metal is chosen from the group consisting of titanium, tantalum, aluminium, silver, zinc, ruthenium, platinum, copper.

According to one example, the first species comprises the metal and alkyl, amine, oxygenated (for example carbonyl) or halogenated ligands.

According to one example, the plasma treatment being performed simultaneously with the injection of the precursor based on the first species, the plasma treatment and the injection of the precursor are each performed by simultaneous or sequential pulses between the plasma treatment and the injection of the precursor. In situ reduction of the precursor is thus performed either in the gas phase, or at the adsorbates. The method obtained may be described as pulsed CVD mode, and self-limiting with the phase shift between the precursor pulse and the plasma treatment. Preferably, according to this example, the first species comprises metal and alkyl ligands.

According to one example, the plasma treatment being performed after the injection of the precursor based on the first species, for example before and/or simultaneously with the injection of the precursor based on the second species, and/or after the injection of the precursor based on the second species, the first species is based on a metal and the second species comprises at least one among the elements oxygen, nitrogen and sulphur. According to the metallic precursor dose deposited, the quantity and reactivity of the precursor based on oxygen, nitrogen or sulphur may be limited to modulate the surface reaction before the injection of the metallic precursor of the following cycle.

According to one example, the plasma treatment being performed simultaneously with the injection of the precursor based on the second species, the second species is chosen from the group consisting of O₂, N₂ (optionally in a mixture with H₂), NH₃, H₂S.

According to one example, the plasma treatment being performed after the injection of the precursor based on the second species, the second species is chosen from the group consisting of H₂O, O₂, NH₃.

According to one example, when the first species is based on a metal and the second species comprises the at least one among the elements oxygen, nitrogen and sulphur, the radiofrequency polarisation power may be less than or equal to 80 W. The pressure in the reaction chamber may be less than or equal to 80 mTorr. The plasma treatment duration during a deposition cycle is less than or equal to 1 minute. Thus, the surface reactivity between the precursor based on the first species, the precursor based on the second species (thermal reactant or plasma) and/or the radicals of the oxidation, nitriding or sulphidising plasma may be activated and/or modified. These plasma conditions can advantageously modify the properties of the deposited material

According to one alternative example, when the first species is based on a metal and the second species comprises the at least one among the elements oxygen, nitrogen and sulphur, the radiofrequency polarisation power may be greater than or equal to 50 W. The pressure in the reaction chamber may be less than or equal to 20 mTorr. The plasma treatment duration during a deposition cycle is greater than or equal to 1 minute. The precursor chemisorbed on the surface may thus be removed, or sputtered. These plasma conditions may be useful for selective depositions on 3D substrates.

According to one example, the plate being configured to be adjusted in height in the reaction chamber, the method comprises an adjustment of the height of the plate prior to the plasma treatment, preferably prior to the deposition cycle. Thus, the distance d may be adjusted by the height of the plate, for example for different pressure or polarisation voltage values, according to needs. The reactor therefore gains in versatility. When the reactor furthermore comprises an inductively coupled plasma source offset from the reaction chamber, this furthermore makes it possible to adjust the distance d between the plate and the lateral wall, which is particularly advantageous in synergy with an additional ICP Source. It is thus possible to couple or uncouple CCP and ICP plasmas according to needs.

According to one example, the plasma treatment is configured such that the plasma has the following ion flow characteristics:
power density: 0.05 to 0.5 W/cm²,
ion flow: 10¹² to 10¹⁴ ions/(cm²·s),
ion energy: 0 to 300 eV.

For this, the pressure in the chamber, the radiofrequency polarisation frequency and the frequency polarisation power may in particular be adapted, as described in more detail hereinafter.

According to one example, the reactor is a plasma-enhanced atomic layer deposition reactor.

According to one example, the reactor is configured to generate a plasma having an ion density substantially less than or equal to 10¹⁴ ions·cm⁻²·s⁻¹. This low-density plasma, localised in the vicinity of the substrate makes it possible to make more refined use of ion bombardment.

According to one example, the distance, and for example the minimum distance, between the upper face of the plate and the lateral wall is between 5 cm and 15 cm, preferably between 5 cm and 12 cm. This distance range allowing discharge self-maintenance is governed by Paschen's law, dependent on the pressure P in the reactor, and the minimum mean voltage Uₘᵢₙ of the RF power: Uₘᵢₙ=P·d. This makes it possible to obtain an ion density ≤10¹⁴ cm⁻²·s⁻¹ for a very low-density plasma, further facilitating adjustment of the plasma characteristics. This furthermore makes it possible to obtain the low-density plasma without overly reducing the pressure in the reaction chamber, for pressures of the order of one mTorr to a few hundred mTorr, for example 200 m Torr.

According to one example, the distance d is proportional, and preferably equal, to the ratio of U/P, P being the pressure in the reactor, and U the mean voltage of the radiofrequency polarisation applied to the plate, U being greater than or equal to a minimum mean radiofrequency self-polarisation voltage value Uₘᵢₙ.

According to one example, the lateral wall is at least partly disposed perpendicularly relative to the main extension plane of the upper face of the plate. The lateral wall is thus substantially vertical.

According to one example, the lateral wall is at least partly disposed obliquely relative to the main extension plane of the upper face of the plate. Edge effects are thus avoided and the field lines on the substrate are attenuated relative to a vertical wall.

According to one example, the lateral wall is disposed relative to the main extension plane of the upper face of the plate, so as to form an angle between 15° and 85°, preferably between 30° and 80°. According to one example, and in particular when the lateral wall is dome-shaped, the tangent of the lateral wall defines an angle between 15° and 85°, preferably between 30° and 80°. The tangent of the lateral wall may be tangent to a point of the lateral wall located in the main extension plane of the upper face of the plate.

According to one example, the electrically conductive lateral wall is at least partly disposed above the plate, in projection along a vertical plane, or substantially perpendicular to the upper face of the plate.

According to one example, the lateral wall has a symmetry of revolution about a perpendicular and substantially centred direction relative to the upper face of the plate. This symmetry allows arcing of the plasma on the entire surface of the upper face. The plasma is therefore more homogeneous.

According to one example, the lateral wall does not have a symmetry of revolution about a perpendicular and substantially centred direction relative to the upper face of the plate. It may for example be provided that the conductive lateral wall only partly surrounds the plate, in projection in a plane parallel with the main extension plane of the upper face of the plate.

According to one example, the lateral wall forms at least partly a cone above the plate, preferably the lateral wall has a conical geometry of substantially centred axis of revolution relative to the plate.

According to one example, the lateral wall forms at least partly a dome above the plate, preferably the lateral wall has at least partly a hemispherical geometry, preferably substantially centred relative to the plate.

According to one example, the reactor is configured such that the plasma is generated only in the reaction chamber by the power applied on the substrate-holder. Thus, the reactor has a simplified configuration, therefore less costly than that of a conventional ICP PEALD reactor.

According to one example, the reactor is configured such that the plasma is generated between two electrodes only and the reactor is configured such that the plate forms one of the two electrode. By way of comparison, in an ICP reactor, the ICP plasma is only generated by a turn supplied by an RF power.

According to one example, the reactor is free from an additional ICP plasma type source.

According to one example, the plate is not configured to be adjusted in height in the reaction chamber. The configuration of the reactor is thus further simplified.

According to one example, the reactor further comprises an inductively coupled plasma source offset from the reaction chamber. The reactor is thus a multimode reactor allowing deposition enhanced by ICP plasma and/or by the plasma generated between the plate and the lateral wall, according to needs. The reactor thus makes it possible to carry out various deposition methods according to needs.

When the reactor further comprises an inductively coupled plasma source offset from the reaction chamber, the reactor may comprise two independent plasma sources which may be used as desired: the power source for CCP coupling and the inductively coupled plasma source for ICP coupling. The polarisation powers applied by these two sources may be set independently.

According to one example, the plate is not configured to be adjusted in height in the reaction chamber.

According to one example, the plate is configured to be adjusted in height in the reaction chamber. Thus, the distance d may be adjusted by the height of the plate, for example for different pressure or polarisation voltage values, according to needs. The reactor therefore gains in versatility. When the reactor further comprises an inductively coupled plasma source offset from the reaction chamber, the distance d between the plate and the lateral wall may be adjusted, which is particularly advantageous for modulating the properties of the plasma in the vicinity of the substrate. It is thus possible to uncouple or couple the two CCP and ICP type plasmas according to needs.

According to one example, the gaseous precursor intake and the pumping module are configured to maintain, at least when the plasma is generated, a pressure substantially between 5 and 200 mTorr, preferably between 5 mTorr and 100 mTorr in the reaction chamber, preferably between 5 mTorr and 80 mTorr in the reaction chamber, at least when the plasma is generated. These pressures correspond to a high secondary vacuum.

According to one example, the gaseous precursor intake and the pumping module are configured to maintain a pressure substantially less than or equal to 200 mTorr, preferably 100 mTorr in the reaction chamber, at least when the plasma is generated.

According to one example, the gaseous precursor intake and the pumping module are configured to maintain a pressure substantially greater than or equal to 10 mTorr in the reaction chamber, at least when the plasma is generated, preferably greater than or equal to 15 mTorr.

According to one example, the power source is configured to apply the radiofrequency power with a frequency between 2 and 100 MHZ, when the plasma is generated by capacitive coupling between the plate and the lateral wall, or in an equivalent manner to generate a capacitively coupled plasma between the plate and the lateral wall.

According to one example, the power source (for CCP coupling) is configured to apply the radiofrequency power with a power less than or equal to 100 W, when the plasma is generated by capacitive coupling between the plate and the lateral wall. According to one example, a non-zero radiofrequency power less than or equal to 100 W is applied to the plate.

The inductively coupled plasma source offset from the reaction chamber may be configured to apply a radiofrequency power with a non-zero power in absolute value between 0 and 300 W.

According to one example, the method further comprises an adjustment of at least two plasma parameters, these parameters comprising the distance d, the pressure P in the reactor, the mean voltage U of the radiofrequency power applied to the plate, such that:
d is proportional, and preferably equal, to the ratio of U/P,
U is greater than or equal to a minimum mean self-polarisation voltage Umin. Preferably, this adjustment is performed before the plasma treatment of the exposed surface. Thus, the parameters may be adjusted without impacting the deposition on the substrate.

According to one example, the reactor plate being configured to be adjusted in height in the reaction chamber, the method comprises an adjustment of the distance d by a height movement of the plate, so as to reach a distance d allowing plasma generation. It is thus possible to be placed at a distance not allowing plasma generation, and move the plate until a plasma is observed. Preferably, this adjustment is performed before the plasma treatment of the exposed surface.

According to one example, during the plasma treatment, the pressure in the reaction chamber is substantially between 5 and 200 mTorr, preferably between 5 mTorr and 100 mTorr. For example, the precursor supply may be configured to reach this pressure prior to plasma generation. The gaseous precursor intake and the pumping module may be configured to maintain this pressure.

According to one example, when the adjustment of the plasma parameters is carried out, the method further comprises an application of the radiofrequency power. The above parameters make it possible to obtain the following ion flow characteristics of the plasma at the plate:
power density: 0.05 to 0.5 W/cm²,
ion flow: 10¹² to 10¹⁴ ions/(cm²·s),
ion energy: 0 to 300 eV.

According to one example, the power source comprises an attenuator configured to limit the radiofrequency polarisation power of the plasma generated by capacitive coupling.

In the following description, the term “on” does not necessarily mean “directly on”. Thus, when it is indicated that a part or a member A bears “on” a part or a member B, this does not mean that the parts or members A and B are necessarily in direct contact with the other. These parts or members A and B can either be in direct contact or bear on one another through one or more other part(s). The same applies for other expressions such as the expression “A acts on B” which could mean “A acts directly on B” or “A acts on B through one or more other part(s)”.

In the present patent application, the term movable corresponds to a rotational movement or to a translational movement or to a combination of movements, for example the combination of a rotation and a translation.

In the detailed description hereinafter, terms such as “horizontal”, “vertical”, “longitudinal”, “transverse”, “upper”, “lower”, “top”, “bottom”, “front”, “rear”, “inner”, “outer” may be used. These terms must be interpreted relatively in relation to the normal position of use of the reactor. For example, the terms “horizontal” and “longitudinal” correspond to the main extension direction of the upper face of the plate.

A reference frame will also be used where the longitudinal or left/right direction corresponds to the x axis, the transverse or rear/front direction corresponds to the y axis and the vertical or bottom/top direction corresponds to the z axis.

A microelectronic device is understood to mean any type of device made using microelectronic means. In addition to devices intended for purely electronic purposes, these devices in particular include micromechanical or electromechanical devices (MEMS, NEMS, etc.) as well as optical or optoelectronic devices (MOEMS, LEDs, etc.).

This may consist of a device intended to carry out an electronic, optical, mechanical function, etc. This may also consist of an intermediate product only intended for making another microelectronic device.

Moreover, a plasma based on a species may be based on or in an equivalent manner formed from a chemistry comprising only this species and optionally one or more other species, for example a rare gas such as argon or helium.

The term “step” should be understood as the completion of a portion of the method, and could refer to a set of sub-steps. The term “step” does not necessarily mean that the actions conducted during a step are simultaneous or immediately successive. In particular, some actions of a first step may be followed by actions related to a different step, and other actions of the first step could be carried on afterwards. Thus, the term “step” does not necessarily mean unitary actions that are inseparable over time and in the sequence of the phases of the method.

In the present patent application, when a gas mixture is expressed with percentages, these percentages correspond to fractions of the total flow rate of the gases injected into the reactor. Thus, if a gas mixture, for example intended to form a plasma, comprises x % of gas A, this means that the injection flow rate of gas A corresponds x % of the total flow rate of the gases injected into the reactor to form the plasma.

A parameter that is “substantially equal to/greater than/less than” a given value is understood to mean that this parameter is equal to/greater than/less than the given value, to within more or less 10% of this value. A parameter that is “substantially between” two given values is understood to mean that this parameter is at least equal to the lowest value given, to within more or less 10%, of this value, and at most equal to the highest value given, to within more or less 10%, of this value.

The plasma-enhanced atomic layer deposition method 4 and the reactor 1 are now described in more detail according to embodiment examples.

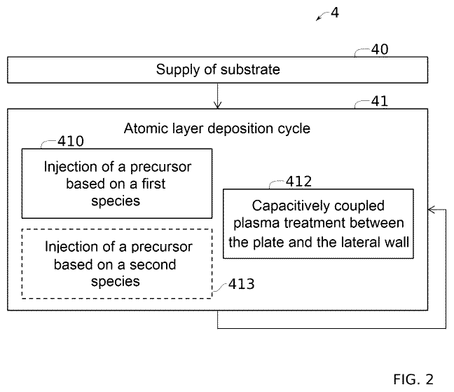

FIG. 2 illustrates the method 1 according to an embodiment example. Optional steps are indicated with dotted lines. The method 4 first comprises supply 40 of a substrate 2 having an exposed surface 20. This substrate 2 is supplied into a plasma reactor 1 comprising a reaction chamber 10. The reactor 1 is configured so as to generate a capacitively coupled plasma between a plate 110 and a lateral wall 100 of the reaction chamber 10 of the reactor 1. Examples of plasma reactor 1 will be described in more detail hereinafter.

Following the supply 40 of the substrate 2, the method 4 comprises a plurality of atomic layer deposition cycles 41 on the exposed surface 20 of the substrate 2. A deposition cycle 41 comprises an injection into the reaction chamber 10 of a precursor based on a first species 410. The cycle 41 further comprises a plasma treatment 412 of the exposed surface 20 of the substrate 2 by the plasma generated by capacitive coupling between the plate 110 and the lateral wall 100 of the reaction chamber 10. As will be seen hereinafter, any relative order between the precursor injection(s) and the plasma treatment may be envisaged, including a plasma treatment followed by the precursor injection(s).

The plasma is generated by applying a radiofrequency power to the plate 110. The plasma is thus generated in a localised manner in the vicinity 3 of the substrate 2 with a much lower ion flow than for a conventional CCP reactor. This reactor 1 makes it possible to make use of low-energy ion bombardment to improve the properties of the material (density, purity, crystalline structure, internal stress). Furthermore, it opens up new development pathways of methods relating to metals, oxides, nitrides and sulphides on 2D and 3D substrates, as well as surface and topographic selective deposition methods.

As illustrated in FIG. 2, the cycle 41 may further comprise an injection of a precursor based on a second species 413. The cycle 41 may be repeated a number of times n so as to reach the desired layer thickness. According to the relative order between the precursor injections 410, 413 and the plasma treatment 412, as well as according to the parameters of the plasma treatment 412, the surface reactions and therefore the properties of the growth layer may be modified. Several examples of deposition cycle 41 are described hereinbelow as non-limiting examples. It is understood that these features may be combined to arrive at other embodiment examples, unless explicitly mentioned otherwise.

According to example, the plasma treatment 412 is performed simultaneously with at least one injection 410, 413 or following at least one of these injections 410, 413 in the reaction chamber 10. Simultaneously means that the plasma treatment 412 is carried out at least partly at the same time as the injection(s) 410, 413 in question. An interval may be provided between the plasma treatment 412 and the injection(s) 410, 413.

During the development of the invention, several plasma treatment modes were demonstrated, according to the sought deposition. According to a first example, the polarisation power may be less than or equal to 80 W, the pressure at the reaction chamber 10 may be less than or equal to 80 mTorr, and the duration of the plasma treatment 412 during a cycle 41 may be less than or equal to one minute. These parameters make it possible to activate and/or modify the surface reactivity between the precursor injections, of the same cycle 41 or between successive cycles. In particular, these parameters make it possible to adjust the reactivity of the ligands of the precursors to influence the growth layer. According to a second example, the radiofrequency polarisation power may be greater than or equal to 50 W, the pressure at the reaction chamber 10 may be less than or equal to 20 m Torr, and the duration of the plasma treatment 412 during a cycle 41 may be greater than or equal to one minute. These parameters make it possible to remove the precursor chemisorbed on the surface. The deposited material can thus grow on localised layer portions. These conditions therefore allow selective deposition, for example on 3D substrate.

Each injection 410, 413 and/or each plasma treatment 412 may be followed by a purging phase 414. This purging 414 makes it possible to remove the species which are not deposited on the exposed surface 20 of the substrate 2, and remove reaction products.

During plasma generation, the plasma treatment 412 may comprise injection of a rare gas, also referred to as inert gas, such as helium or argon, into the reaction chamber 10. This gas may furthermore be in a mixture with dihydrogen H₂. Indeed, an argon-based plasma is low-energy relative to other species. The surface reactions may be modulated even more finely, synergistically with the low-density capacitive plasma generated, while limiting the risk of damaging the exposed surface 20.

The plasma treatment 412 using a capacitive plasma generated between the plate 110 and the lateral wall 100, and therefore a low-density plasma, the method 4 allows depositions of layers of varied kinds and in particular of layers for which the deposition by conventional plasma-enhanced deposition methods remains limited.

For example, the method 4 makes it possible to deposit a metallic layer on the exposed surface 20 of the substrate 2. Examples of metallic layer deposition are now described.

The cycle 41 may comprise injection of a precursor based on a metal 410. A cycle 41 may comprise only one injection of a precursor based on a first metal. The cycle 41 may alternatively comprise an injection of a second precursor based on a metal 413a and in particular a precursor based on a separate metal from the first metal. When several precursors based on different metals are used, the method allows the deposition of a metal alloy layer.

To deposit a metallic layer, the precursors injected during a cycle are preferably all based on a metal. A precursor of a gas injected into the chamber 10 during the plasma treatment 412, intended to form the reactive atmosphere of the plasma such as a neutral gas or hydrogen H₂ is distinguished, this gas being capable of not comprising metal according to this example.

To deposit a metallic layer, the plasma treatment 412 may be performed simultaneously with and/or after the injection of the first precursor based on a metal 410. Alternatively or additionally, the plasma treatment 412 may be performed simultaneously with and/or after the injection of the second precursor 413a. Thus the plasma treatment 412 makes it possible to remove the ligand from the metallic precursor. This promotes metal-on-metal absorption during layer growth by creating pendant bonds.

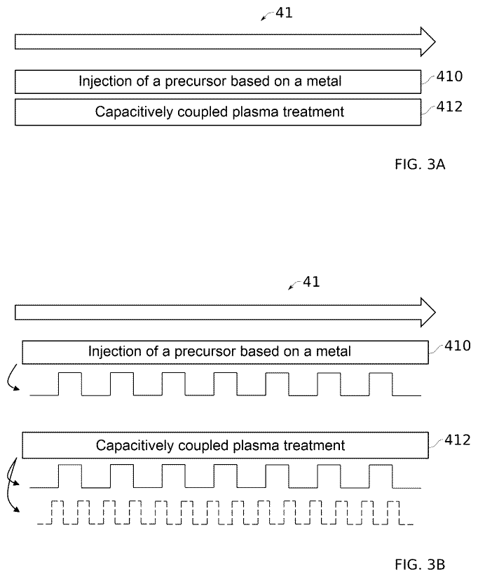

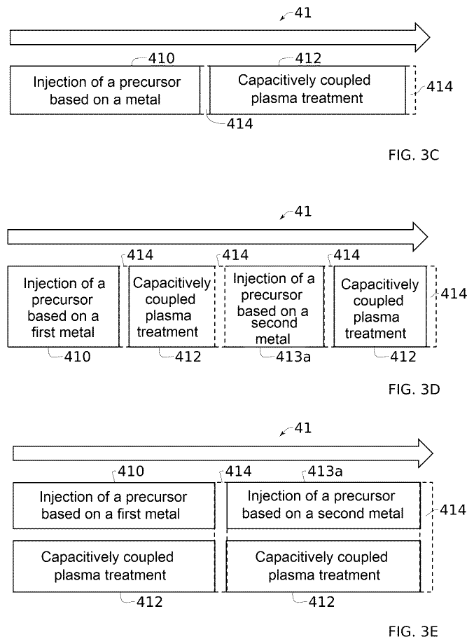

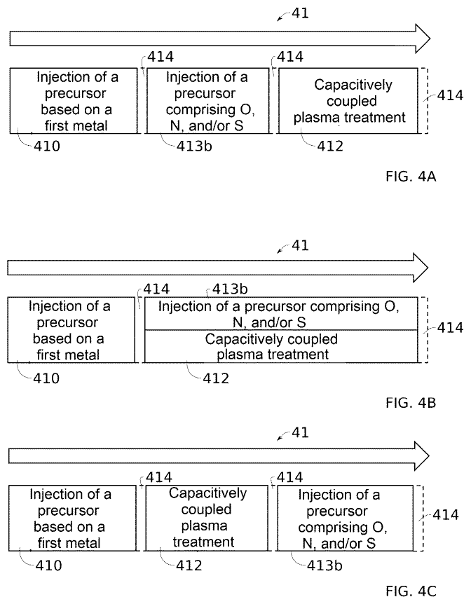

As for example illustrated by FIG. 3A, the cycle 41 may comprise an injection 410 of a precursor based on a metal. Simultaneously with this injection, the plasma treatment 412 may take place.

According to one example, the injection and/or the plasma treatment may be continuous. According to one example, the injection 410 and/or the plasma treatment 412 may be intermittent in a cycle 41. Use of pulses, and in particular precursor pulses, may make it possible to modulate growth mechanisms. These pulses are particularly advantageous for metallic layer deposition, and in particular for pendant bond creation, by H₂/Ar or Ar only plasma. It is indeed more difficult to form this type of layer compared to oxides/nitrides/sulphides which are much easier to form by ligand reactivation (chemical substitution).

As illustrated by FIG. 3B, the plasma treatment 412 may comprise several plasma pulses. In a cycle 41, the application of the radiofrequency power to the plate 110 may be intermittent so as to generate plasma only intermittently, i.e. the plasma treatment 412 may comprise phases of application of RF power separated by phases of non-application of RF power to the plate 110. Similarly, the injection 410 may be intermittent, i.e. the injection 410 may comprise phases of injection of the precursor based on a metal into the chamber 10 separated by phases of non-injection of the precursor into the chamber 10. The phases of RF power application and injection respectively form the pulses. As illustrated by FIG. 3B, these pulses may be simultaneous between the injection 410 and the plasma treatment 412. Alternatively as illustrated with dotted lines in FIG. 3B, these pulses may be offset over time.

Note that this example of plasma pulses and/or pulses during injection of a precursor may apply for injection of a precursor based on a second metal 413a. This may apply for only some of the injections 410, 413a or for each injection 410, 413a of a cycle 41.

Preferably, the plasma treatment 412 and injection of a precursor 410, 413a are each performed for simultaneous or sequential pulses. “Sequential” means that the pulses are not completely simultaneous between the injection and the plasma treatment, and preferably the pulses do not overlap temporally between the injection and the plasma treatment. This allows an in-situ reduction of the precursor either in gaseous phase or at adsorbates on the exposed layer 20 of the substrate 2. The pulse duration may be substantial identical between injection 410,413a and the plasma treatment 412 or these durations may be independent. This mode is self-limiting with the phase shift between the precursor pulse and the plasma treatment. As the metallic precursor does not react with itself, once the surface of the substrate is saturated by the adsorbates, no further reaction can occur. The plasma treatment makes it possible to reduce the ligands of the adsorbate, and a new metallic precursor pulse may once again generate new adsorbates, by release from anchoring sites. The pulse durations for the injection of the precursor and for the plasma treatment may be adapted according to the circumstances, and in particular according to the expansion sustained by the precursor at its entry into the chamber. For example, the precursor injection may be ≤1 s of opening and the plasma duration may be ≤20 s.

Preferably, when a precursor based on a metal is injected by pulsing, the precursor comprises the metal and alkyl ligands. The ligand is preferably non-halogenated, because a halogenated ligand may possibly damage the reactor wall by forming an etching chemistry. Furthermore, halogens being strongly electronegative, they strengthen the Metal-Halogen bond, which makes creating pendant bonds all the more difficult.

According to one example, as illustrated by FIGS. 3C and 3D, an injection of a precursor based on a metal 410,413a may be followed by a plasma treatment 412. This may apply for the injection of the precursor based on the first metal 410 as illustrated in FIG. 3C, and/or for the injection of the precursor based on a second metal 413a as illustrated in FIG. 3D.

As illustrated in FIG. 3E, when the cycle 41 comprises several injections of precursor based on a metal 410, 413a, each injection may be performed simultaneously with a plasma treatment 412, an injection and the associated plasma treatment 412 being separated from the injection 413a and the next plasma treatment 412 by a purging phase 414.

Note that combinations of these examples are possible, with for example an injection of a precursor based on a first metal 410 simultaneously with a plasma treatment 412, followed by an injection of a precursor based on a second metal 413a itself followed by a plasma treatment 412.

According to one example, the plasma treatment 412 may comprise an injection of argon in a mixture with dihydrogen in the reaction chamber 10, for example when the plasma treatment 412 follows the injection of a precursor based on a first metal as illustrated in FIG. 3C. When the plasma is generated, the plasma treatment 412 may not comprise an injection of hydrogen into the reaction chamber 10. Indeed, during the development of the invention, it was demonstrated that it was not necessary to inject a reducing gas such as hydrogen into the chamber to reduce the deposited metal. The properties of the plasma generated by capacitive coupling combined with the injection of the metallic precursor(s) are sufficient to grow a metallic layer on the exposed surface 20 of the substrate 2. This is particularly the case when the injection 410,413a and the plasma treatment 412 are simultaneous, and especially when the metallic precursor contains alkyl type ligands. When the plasma treatment 412 and/or injection of a precursor 410,413a are performed by pulsing, the plasma treatment nevertheless preferably comprises an injection of dihydrogen into the reaction chamber 10. In simultaneous injection, it is preferable to avoid a reactive plasma (for example based on H₂) at the risk of destroying the precursor and a CVD type growth (i.e. not layer/layer, as not self-limited) will be obtained. In sequential mode, using a reactive plasma can be permitted, because only the adsorbate ligands will be treated by this plasma.

Concerning the plasma generation parameters, for metallic layer growth, preferably these parameters are chosen so as to modify and/or remove the precursor ligands to promote the deposition of a metallic layer by metal-on-metal adsorption. For this, the radiofrequency polarisation power may be less than or equal to 80 W, the pressure in the reaction chamber 10 may be less than or equal to 80 mTorr, and the duration of the plasma treatment during a cycle 41 may be less than or equal to one minute. The deposited dose is thus limited which improves the removal of the ligand without risking removing the deposited metal.

Concerning the type of metal, this method is particularly adapted for deposition of the metals titanium, tantalum, aluminium, silver, zinc, ruthenium, platinum, copper.

The precursor based on the first metal and the precursor based on the second metal are preferably organometallic precursors dedicated for ALD methods. The method may be adapted according to the metallic precursor. For example, for a chlorinated metallic precursor, an N₂/H₂ plasma will preferably be chosen. For an organometallic precursor, an inert plasma, and in particular an Ar plasma, is rather chosen to remove the organic ligand.

Examples of deposition are now described with reference to FIGS. 4A to 4C.

In order to deposit a metal oxide, nitride and/or sulphide layer on the exposed surface 20, the method comprises the injection of a precursor based on a metal 410 and an injection of a precursor comprising the at least one among the elements oxygen, nitrogen and sulphur 413b. Preferably, in a cycle 41, the injection of the precursor based on oxygen, nitrogen and/or sulphur 413b follows the injection of the metal-based precursor 410. The plasma treatment 412 may be performed before and/or simultaneously with and/or after the injection of the precursor based on oxygen, nitrogen and/or sulphur 413b. Thus the quantity and reactivity of the precursor based on oxygen, nitrogen and/or sulphur are limited so as to modulate the surface reactivity before the injection of the metal-based precursor 410 of the following cycle 41. According to the relative order between the plasma treatment 412 and the injection of the precursor based on oxygen, nitrogen and/or sulphur 413b, this precursor may be denoted by the term “thermal reactant” when the plasma treatment 412 follows the injection 413b, or “plasma reactant” when the plasma treatment 412 is simultaneous with the injection 413b.

As illustrated in FIG. 4A for example, the injection of the metal-based precursor 410 may be followed by the injection of the precursor based on oxygen, nitrogen and/or sulphur 413b, in turn followed by the plasma treatment 412. According to this example, the precursor based on oxygen, nitrogen and/or sulphur may be chosen from the group consisting of H₂O, O₂, NH₃, or O₃ with an ozoniser. The metallic precursor may be heat-treated by the second precursor before the plasma treatment 412. The plasma treatment 412 may be argon-based.

According to a second example, for example illustrated by FIG. 4B, the injection of the metal-based precursor 410 may be followed by the injection of the precursor based on oxygen, nitrogen and/or sulphur 413b, in turn performed simultaneously with the plasma treatment 412. According to this example, the precursor based on oxygen, nitrogen and/or sulphur may be chosen from the group consisting of O₂, N₂, NH₃ and H₂S. H₂O and O₃ precursors are not used as they are not plasma-forming. In the case of H₂S, a simultaneous plasma treatment is required to activate the reaction energy. A layer respectively of metal oxide, nitride or sulphide is therefore deposited preferably when the injection of the second precursor 413b is simultaneous with the plasma treatment 412. The precursor based on oxygen, nitrogen and/or sulphur may be injected 413b with argon.

According to a third example, illustrated by FIG. 4C, the injection of the metal-based precursor 410 may be followed by the plasma treatment 412, the latter being followed by the injection of the precursor based on oxygen and/or nitrogen, and/or sulphur in the case where a plasma treatment is also performed simultaneously with the sulphur injection 413b.

The two plasma treatment 412 modes described above may be used for deposition of an oxide, nitride and/or sulphide layer. According to a first example, the radiofrequency polarisation power may be less than or equal to 80 W, the pressure in the reaction chamber may be less than or equal to 80 mTorr, and the duration of the plasma treatment during a deposition cycle may be less than or equal to 1 minute. These parameters make it possible to adjust the surface reactivity between the metal-based precursor, the precursor based on oxygen, nitrogen and/or sulphur (thermal or plasma reactant), as well as the plasma radicals.

According to a second example, the radiofrequency polarisation power may be greater than or equal to 50 W, the pressure in the reaction chamber may be less than or equal to 20 mTorr, and the duration of the plasma treatment during a deposition cycle may be greater than or equal to 1 minute. Thus, here again, the precursor chemisorbed on the surface may be removed. The deposited material can thus grow on localised layer portions. These conditions therefore allow selective deposition, for example on 3D substrate.

According to one example, the metal-based precursor comprises the metal and an amino group. In the case of an amino precursor, an adjustment of the dose (duration and energy of ion flow) by the plasma parameters makes it possible to desorb the ligand from the metal in order to deposit the metal atomic layer, but also break the N—C bond of the ligand to facilitate nitride deposition. For example, the precursor may have one of the chemical formulas hereinbelow.

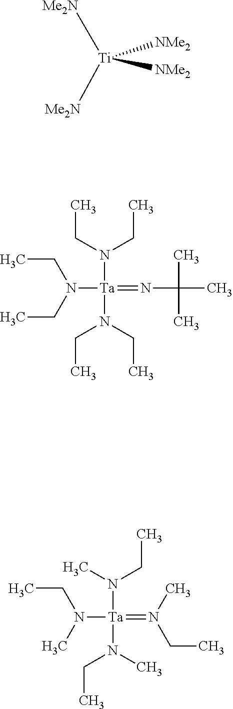

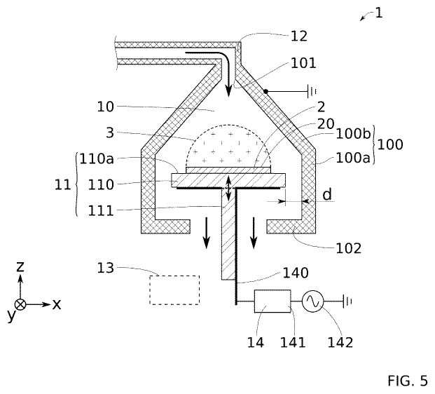

Examples of reactor 1 are now described with reference to FIGS. 5 to 8. Plasma treatment 412 parameters are furthermore described.

The reactor 1 is more particularly intended for plasma-enhanced atomic layer deposition.

The reactor 1 comprises a reaction chamber 10 intended to accommodate a substrate 2 and wherein the deposition is intended to be performed. This chamber 10 is delimited by one or more lateral walls 100, an upper wall 101 and a lower wall 102.

To perform the deposition of a layer on the substrate 2, the reactor 1 comprises intake and discharge means of gaseous precursor(s) and/or gaseous species for plasma formation. The reactor 1 comprises a gaseous precursor intake 12 configured to convey gaseous precursors into the chamber 10, as illustrated by the arrow at the top of the reactor in FIGS. 5 to 8. The gaseous precursor intake 12 may furthermore be configured to introduce into the chamber 10 gases for plasma formation, for example rare gases such as helium or argon. The reactor 1 further comprises a pumping module 13 of the chamber 10. The pumping module 13 makes it possible to discharge the gaseous species present in the chamber, as illustrated by the two arrows at the bottom of the reactor in FIGS. 5 to 8. These species may in particular be discharged between different ALD deposition cycles. The pumping module 13 furthermore makes it possible, with the intake 12, to maintain a given pressure inside the chamber 10, typically lower than atmospheric pressure.

The substrate 2 is accommodated in the reaction chamber 10 by a sample-holder 11. The sample-holder may comprise a plate 110 configured to receive the substrate 2, connected to an arm 111. The plate 110 may in particular have a planar upper face 110a supporting the substrate 2. The upper face 110a is for example substantially horizontal. Note that the plate 110 may have other inclined faces, for example on the edges or a rounded lower face.

The reactor 1 is configured such that a plasma is generated by capacitive coupling between the upper face 110a of the plate 110 and the lateral wall 100, polarised at the ground as illustrated in FIGS. 5 to 8. For this, the plate 110 is electrically conductive. The plate 110 may be at least partly formed from an electrically conductive material. The lateral wall 100 is at least partly electrically conductive. The lateral wall 100 may be at least partly formed from an electrically conductive material. The reactor 1 further comprises a power source 14 configured to apply a radiofrequency power to the plate 110. The power source 14 may for example comprise a radiofrequency power generator 142 connected to a radiofrequency transmission member 140 to the plate 110.

This power source 14 may comprise a regulation device 141 and makes it possible to induce an RF voltage, also referred to as self-polarisation voltage, on the plate 110 to generate the CCP plasma. Preferably, this regulation device 141 comprises an auto match unit which adapts the impedance of the plasma in the chamber 10 to that of the radiofrequency power generator 142 so as to minimise the reflected power and allow discharge self-maintenance. This power source 14 is configured to generate the plasma and allow self-polarisation of the plate 110. Indeed, the plasma is supplied with power, and the match unit adapts the impedance to minimise the reflected power and allow discharge self-maintenance. Plasma is an electric discharge having its own impedance dependent on its degree of ionisation and the gas chemistry, as well as the geometric reactor and electrical power supply parameters. The self-polarisation voltage may typically be from 50 V to 300 V for a power varying from 10 W to 100 W in a reactor receiving substrates of maximum diameter 200 mm. The regulation device 141 may in particular comprise an attenuator configured to limit the power of the generator 142.

The lateral wall 100 is at least partly non-parallel with the upper face 110a of the plate 110. The upper face 110a of the plate 110 and the lateral wall 100, at least on its part non-parallel with the upper face of the plate, are separated by a distance d configured so as to generate a plasma by capacitive coupling between the plate 110 and the lateral wall 100, each acting as an electrode for plasma generation. During the development of the invention, it was indeed demonstrated that non-parallel arrangement of the lateral wall 100 and the upper face 110a, coupled with a certain distance d, made it possible to generate the plasma by capacitive coupling in the vicinity of the substrate 2, at a zone for generating plasma 3.

The plasma is thus generated in a localised manner in the vicinity 3 of the substrate 2 with a much lower ion flow than for a conventional CCP reactor. This reactor 1 makes it possible to make use of low-energy ion bombardment to improve the properties of the material (density, purity, crystalline structure, internal stress). Furthermore, as described above with reference to the method 4, this opens up new development pathways of methods relating to metals, oxides, nitrides and sulphides on 2D and 3D substrates, as well as surface and topographic selective deposition methods. This reactor 1 therefore makes it possible to perform depositions of varied kinds, unlike existing reactors which are more limited. Indeed, this plasma generation mode makes it possible to perform metallic layer depositions, in particular of transition metals and/or rare earths. Oxide, nitride and/or sulphide layer depositions are furthermore possible, in particular of transition metals and/or rare earths.

The distance d allowing plasma discharge self-maintenance is governed by Paschen's law, dependent on the pressure P in the reactor, and the minimum mean RF self-polarisation voltage Uₘᵢₙ: Uₘᵢₙ=P·d. Therefore, it is understood that the distance d may vary according to the pressure P in the chamber 10 and the minimum mean voltage Uₘᵢₙ set by the power source 14.

This distance d is the shortest distance between the two electrodes formed by the plate 110 and the lateral wall 100. This distance may for example be the distance between one or the two end edges of the plate 110 and the lateral wall 100, and more particularly between one or the two end edges of the upper face 110a of the plate 110 and the lateral wall 100, preferably between an upper face of the plate 110 and the lateral wall 100, and more particularly between one or the two end edges of the upper face 110a of the plate 110 and the lateral wall 100. During plasma generation, the plate 110 and the lateral wall 100 are distant from one another by the distance d.

According to one example, the distance d between the upper face 110a of the plate 110 and the lateral wall 100 is between 5 cm and 15 cm, preferably between 5 cm and 12 cm, and even more preferably between 5 and 8 cm. This range of distance d applies for example for a pressure PŬ≤80 m Torr (where 1 mTorr=10³ Torr and 1 Torr=133.322 Pa), and Umin (self-polarisation voltage) for which the absolute value is substantially between 0 V exclusive and 300 V 10 V; 300 V], preferably between 50 V and 300 V [50 V; 300 V], and more preferably between 100 V and 300 V. A sufficiently low ion flow, substantially less than or equal to 10¹⁴ cm⁻²·s⁻¹, may thus be obtained.

For the capacitively coupled ALD deposition according to the invention, the pressures are of the order of one mTorr to a few hundred mTorr, for example 200 mTorr. The radiofrequency power typically applied is less than or equal to 100 W, this power being non-zero. The pressure, self-polarisation voltage and distance parameters are interdependent to obtain capacitively coupled plasma generation. As will be described in more detail hereinafter, it is possible in the reactor 1 for d to be set, and that the self-polarisation voltage and the pressure be adjusted within the corresponding ranges hereinabove. Alternatively, the distance d may be adjustable for example with means for setting the height of the plate 110, as described hereinafter.

Note that the type of gas may have an influence on Paschen's law. These data are tabulated and known to a person skilled in the art, as for example described for argon in C. Torres, P. G. Reyes, F. Castillo, H. Martinez, Journal of Physics: Conference Series; Bristol Vol. 370, No. 1, (June 2012). A person skilled in the art will therefore be able to adapt these parameters for example by adjusting the self-polarisation voltage and the pressure, d being fixed, or additionally by adjusting the distance d, in particular within the aforementioned ranges.

In order to generate the plasma, the electrically conductive lateral wall 100 may be at least partly disposed above the plate 110, in projection from said wall on a perpendicular plane to the upper face 110a of the plate 110. It is therefore understood that at least a part of the wall 100 is disposed facing the upper face of the plate, such that the capacitively coupled plasma may be generated between the lateral wall 100 and the upper face 110a of the plate 110, wherein the substrate 2 is placed.

According to one example, the reaction chamber 10 and more particularly the lateral wall 100 has a symmetry of revolution about a direction parallel with the z axis and substantially centred relative to the upper face 110a of the plate 110. This symmetry allows arcing of the plasma on the entire surface of the upper face 110a of the plate 110. Once the plasma is ignited, it is propagated on the entire lower electrode (the upper face 110a of the plate 110). The plasma is therefore more homogeneous.

According to one example, the lateral wall 100 is disposed vertically relative to the main extension plane (x, y) of the upper face 110a of the plate 110. However, a vertical wall generates very close field lines on the edges of the substrate, and therefore a more localised (and therefore higher-energy) plasma. A more localised plasma may generate breakdown phenomena at the edges of the substrate and therefore edge effects.

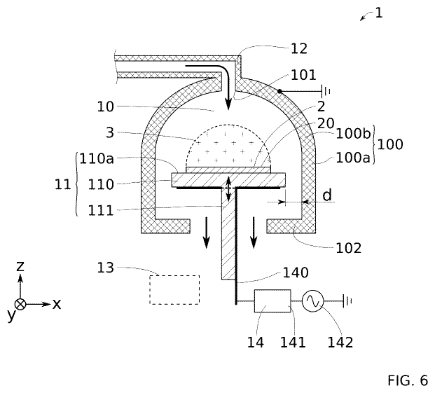

To limit this, as illustrated by FIGS. 5 and 6, the lateral wall 100 is preferably at least partly disposed obliquely relative to the main extension plane (x, y) of the upper face 110a of the plate 110. Equivalently, the lateral wall is disposed neither parallel with nor perpendicularly to the main extension plane (x, y) of the upper face 110a. This oblique arrangement makes it possible in particular to improve the plasma obtained by limiting edge effects. The plasma generated is thus made more homogeneous for a better layer deposition.

The lateral wall 100 may comprise several portions 100a, 100b. A first portion 100a may be disposed substantially perpendicularly to the main extension plane (x, y) of the upper face 110a. A second portion 100b may be disposed obliquely relative to the main extension plane (x, y) of the upper face 110a of the plate 110. Hereinafter, the portion 100b of the lateral wall is considered in a non-limiting way as disposed obliquely relative to the plane (x, y).

As for example illustrated by FIG. 5, the second portion 100b of the lateral wall 100 may have a conical geometry above the plate 110. This geometry may more particularly be chosen according to the distance d. The portion 100b may for example be in the form of a cone truncated by the upper wall 101. A truncated cone geometry allows the lateral wall not to form hollows wherein the species generated by the plasma could accumulate. Preferably, the second portion 100b has a conical geometry of substantially centred axis of revolution relative to the plate 110.

As for example illustrated by FIG. 6, the second portion 100b of the lateral wall 100 may form a dome above the plate 110. The portion 100b may for example be in the form of a hemisphere above the plate 110. Once again, this geometry may more particularly be chosen according to the distance d. A dome-shaped geometry, and more particularly a hemispherical geometry makes it possible to have a smaller chamber volume (therefore less reagents consumed, chamber easier to pump), and limit the dead volume in the chamber. Preferably, the second portion 100b has a hemispherical geometry, preferably substantially centred relative to the plate 110. The dome may be truncated by the upper plate 101. Alternatively, the lateral wall 100 may form a non-truncated dome.

It is understood, for example with reference to the domed geometry described above, that the lateral wall 100 may extend so as to form all or part of the upper wall 101.

According to one example, the plate 110 may be non-adjustable in height in the chamber 10. Equivalently, the plate 110 may be non-movable at least along the vertical direction z in the chamber 10. However, it may be provided that the plate 110 be configured to be movable, for example in rotation, to the set height of the chamber 10, for example to improve deposition uniformity. This rotation may be about the axis of its arm 111. The plate 110 may alternatively be completely fixed in the chamber 10. In particular when the plate 110 is non-adjustable in height, the geometry of the lateral wall 110 may be adapted relative to the sample-holder to obtain the distance d allowing plasma generation. The reactor 1 may thus be of simplified configuration, and therefore less costly.

According to another example, the plate 110 may be adjustable in height in the chamber 10, as illustrated by the vertical double arrow in FIGS. 5 to 8. Equivalently, the plate 110 may be movable at least along the vertical direction z in the chamber 10. Thus, the distance d may be adjusted by the height of the plate 110, for example for different pressure or minimum voltage Uₘᵢₙ values, according to needs. The plasma properties may furthermore be modulated by adjusting the height of the plate 110 while taking care not to extinguish the plasma 3. The height adjustment of the plasma 110 may furthermore be particularly advantageous when the reactor 1 comprises an additional plasma source, as described in more detail hereinafter. Furthermore, it may be provided that the plate 110 be configured to be movable, for example in rotation, for example to improve deposition uniformity. This rotation may here again be about the axis of its arm 111.

The movement(s) of the plate 110 may for example be actuated by a motor, not shown in the figures.

As for example described by FIGS. 5 and 6, the reactor 1 may be configured to only form the plasma by capacitive coupling between the plate 110 and the lateral wall 100 in the reaction chamber. The plasma may in particular be generated between two electrodes only. The plate 110 may form one of the electrodes. The lateral wall 100 may form the other electrode. The reactor 1 may only comprise capacitively coupled generation between the plate 110 and the lateral wall 100 as plasma source. The configuration of the reactor 1 is thus simplified, and therefore less costly. Note that the adjustment or not in height of the plate 110 is possible according to this example.

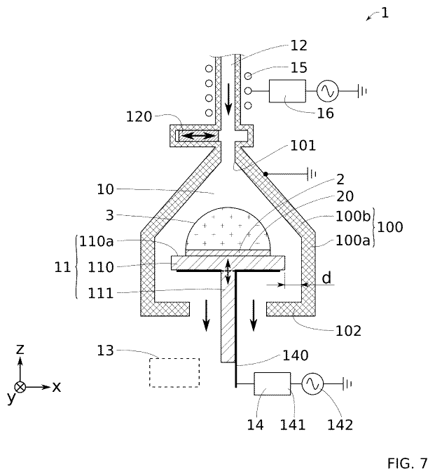

As for example illustrated by FIG. 7, the reactor 1 may comprise an inductively coupled plasma source 15 offset from the chamber 10. The reactor 1 may therefore be an ICP and/or CCP multimode reactor. According to needs, the plasma may be generated in ICP mode and/or in CCP mode. For this, the reactor 1 may comprise a radiofrequency inductive source comprising a coil 15 supplied by a radiofrequency power generation device 16. The power source 14 and the inductive source 15, 16 are configured such that the RF power applied to the plate 110 is independent from the RF power of the inductive source.

When the reactor 1 operates in CCP mode, plasma generation takes place by capacitive coupling between the upper face 110a of the plate 110 and the lateral wall 100 as described above. When the reactor 1 operates in ICP mode, plasma generation is performed by the inductively coupled plasma source 15. The power source 14 may then be used a polarisation device configured to induce a polarisation voltage at the substrate 2 allowing extraction of the ions from the offset plasma with a controlled incident energy when they arrive in the vicinity of the substrate 2.

The gaseous precursor intake 12 may be disposed at the inductive source 15, 16.

The inductive source 15, 16 may be isolated from the chamber 10 by a valve 120 having an open configuration for circulating the plasma species from the source to the chamber 10, and a closed configuration for blocking these species. Note that it may be provided that another gaseous precursor intake be disposed directly at the chamber 10, without passing via the inductive source.

Preferably, when the reactor 1 can comprise an inductively coupled plasma source 15 offset from the chamber 10, the plate 110 is adjustable in height. Thus, according to the distance d obtained between the plate 110 and the lateral wall 100, a plasma may be generated by the inductive source 15, 16 only, or both by the inductive source 15, 16 and by the capacitive coupling between the plate 110 and the lateral wall 100. Note that an adjustment or not in height of the plate 110 is possible according to this example.

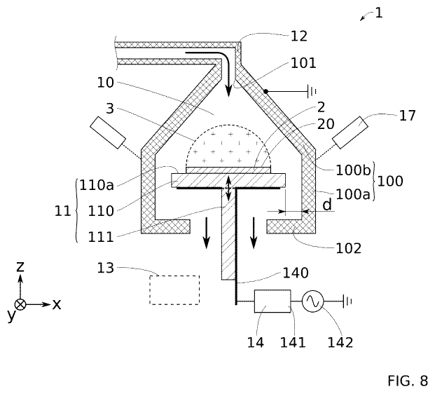

As illustrated for example by FIG. 8, the reactor 1 may furthermore comprise a module 17 for determining the thickness of the deposited layer. This module 17 may for example comprise an ellipsometer coupled with the reactor 1, for example at its lateral wall 100. FIG. 8 is a representation of principle. In practice, the two points of intersection of emitted and reflected rays intersect on the surface of the substrate where growth takes place.

Examples of operating parameters of the reactor 1 are now described.

The RF power and pressure conditions in the chamber 10 make it possible to adapt plasma ion flow characteristics finely.

The gaseous precursor intake 12 and the pumping module 13 may be configured to maintain, at least during the plasma treatment 412, a pressure substantially between 5 and 200 mTorr, preferably between 5 mTorr and 100 mTorr, preferably between 5 m Torr and 80 mTorr in the reaction chamber 10. Preferably, the pressure in the reaction chamber is substantially less than or equal to 100 mTorr at least during the plasma treatment 412.

The power source 14 may be configured to apply the radiofrequency power with a power less than or equal to 100 W.

The power source 14 may be configured to apply the radiofrequency power with a frequency between 2 and 100 MHz when the plasma is generated by capacitive coupling.

Note that when the reactor comprises an inductively coupled plasma source 15, and operates in ICP mode, the power source acting as a polarisation device configured to induce polarisation voltage at the substrate 2 may operate at a higher power and/or at a frequency other than the range specified above.

These parameters in the ranges indicated make it possible to obtain the following ion flow characteristics of the plasma generated between the lateral wall 100 and the plate 110, adapted to PEALD deposition:
power density: 0.05 to 0.5 W/cm²
ion flow: 10¹² to 10¹⁴ ions/(cm²·s)
ion energy: 0 to 300 eV (where 1 eV≈1.60218·10⁻¹⁹ J).

The following table describes examples of plasma generation parameters according to the invention, for an Argon plasma, with no offset ICP source. The distance d corresponding to these measurements is between 5 and 6 cm.

TABLE 1

| Gas | Ar | Ar | Ar | Ar | Ar | Ar | Ar | Ar | Ar | Ar |
|---|---|---|---|---|---|---|---|---|---|---|
| Flow (sccm | 60 | 60 | 60 | 60 | 60 | 60 | 60 | 60 | 60 | 60 |
| or standard | | | | | | | | | | |
| cm³/min) | | | | | | | | | | |
| Pressure | 7 | 7 | 7 | 7 | 7 | 7 | 7 | 7 | 7 | 7 |
| (mTorr) | | | | | | | | | | |
| RF power | 1 | 2 | 3 | 5 | 7 | 8 | 9 | 10 | 70 | 80 |
| applied (W) | | | | | | | | | | |
| Vdc probe (V) | 0 | 0 | 0 | 0 | 0 | 56 | 61 | 67 | 222 | 253 |
| Vdc flexal (V) | 0 | 0 | 0 | 0 | 0 | 56 | 62 | 68 | 233 | 241 |

The parameters Vdc probe and flexal give the self-polarisation voltage, corresponding to the impedance match between the plasma and the match unit of the reactor. Vdc probe given by a probe measurement (which makes it possible to determine the ion flow) and Vdc flexal is given directly by the match unit of the reactor. The reactor is supplied with applied RF power and the self-polarisation voltage remains zero when the plasma is not ignited or is not self-maintained. In this case, all the power is stored in the match unit.

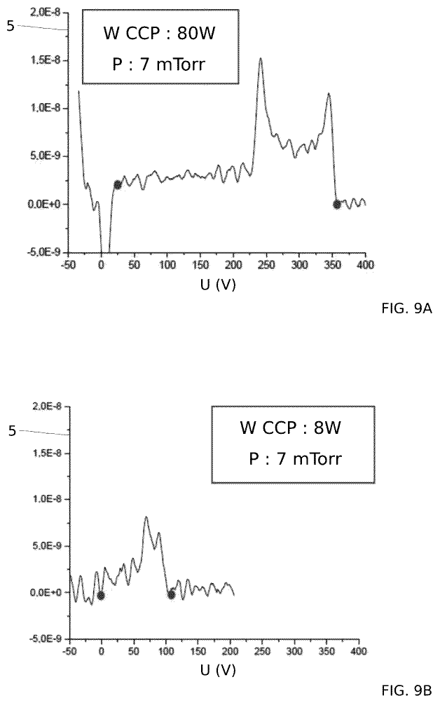

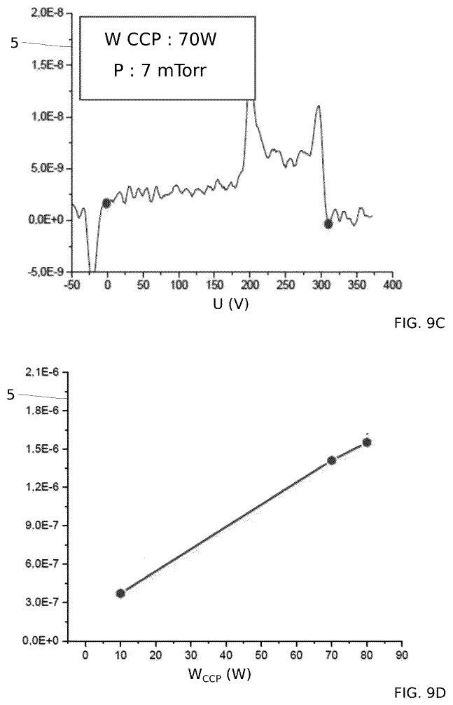

FIGS. 9A to 9D describe, for the parameter examples of Table 1, the effect of the RF power W_{CCP} applied to the plate 110 on the generated ion flow 4 (in arbitrary units), at constant pressure P, and according to the self-polarisation voltage U.

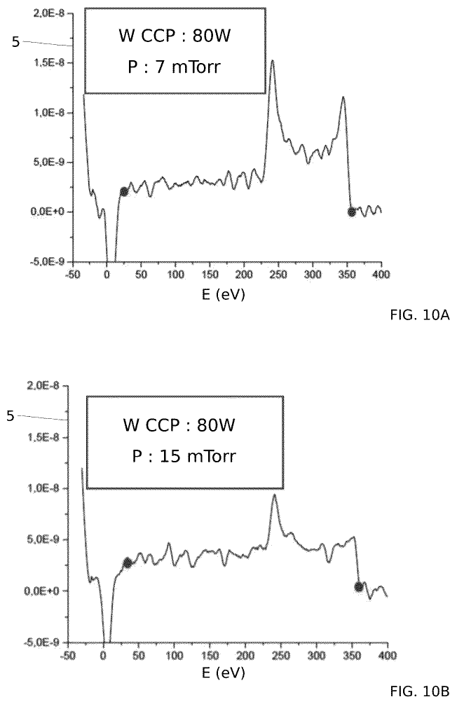

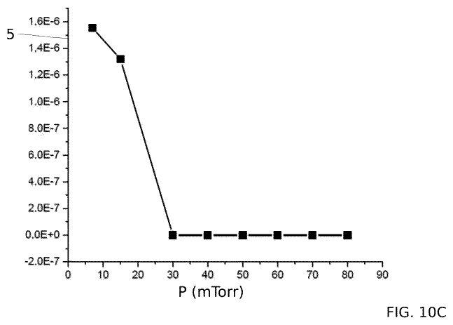

FIGS. 10A to 10C describe, for the parameter examples of Table 1, the effect of the pressure P applied to the plate 110 on the generated ion flow 4 (in arbitrary units), at constant RF power W_{CCP} applied to the plate 110, and according to the self-polarisation voltage U, and according to the ion energy E.

In the light of the preceding description, it is clearly apparent that the invention provides an improved plasma-enhanced deposition solution. The method is improved in particular in terms of deposited layer type and/or deposition selectivity. The PEALD method allows better ion bombardment control, and in particular softer plasma enhancement than existing solutions, and therefore which generate fewer induced defects. It is clearly apparent that the invention provides an improved plasma-enhanced deposition reactor, allowing in particular softer plasma enhancement than existing solutions, and therefore which generate fewer induced defects.

The invention is not limited to the previously-described embodiments and encompasses all of the embodiments covered by the invention. The present invention is not limited to the previously-described examples. Many other variants are possible, for example by combining previously-described features, without departing from the scope of the invention. Furthermore, the features described with regards to one aspect of the invention may be combined with another aspect of the invention. In particular, the method may comprise any step resulting from the implementation of a feature of the reactor and the reactor may have any feature allowing, for example an element configured for, the implementation of a step of the method.

In the examples illustrated, the intake 12 has been represented at the upper face 101 of the reactor 1. Another arrangement, for example at the lateral wall 100, is possible. The same applies for the pumping module 13.

1. A plasma-enhanced atomic layer deposition method comprising:
a supply of a substrate having an exposed surface in a plasma reactor, the plasma reactor comprising a reaction chamber delimited by walls and an electrically conductive plate having an upper face whereon the substrate is disposed, a lateral wall of the reaction chamber being at least partly non-parallel with the upper face of the plate and being electrically conductive,
a plurality of atomic layer deposition cycles on the exposed surface of the substrate, each cycle comprising:
an injection into the reaction chamber of a precursor based on a first species,
a plasma treatment of the exposed surface of the substrate by a plasma generated by capacitive coupling between the plate and the lateral wall, by applying a radiofrequency power to the plate.

2. The method according to claim 1, wherein the plurality of deposition cycles further comprises an injection into the reaction chamber of a precursor based on a second species.

3. The method according to claim 1, wherein the plasma treatment is performed simultaneously with at least one injection into the reaction chamber of a precursor or following at least one injection into the reaction chamber of a precursor.

4. The method according to claim 1, wherein the radiofrequency power is less than or equal to 80 W, the pressure at the reaction chamber may be less than or equal to 80 mTorr, and the duration of the plasma treatment during a deposition cycle is less than or equal to 1 minute.

5. The method according to claim 1, wherein the radiofrequency polarisation power is greater than or equal to 50 W, the pressure in the reaction chamber is less than or equal to 20 mTorr, and the duration of the plasma treatment during a deposition cycle is greater than or equal to 1 minute.

6. The method according to claim 1, wherein when the plasma is generated, the plasma treatment comprises the injection into the reaction chamber of a rare gas.

7. The method according to claim 1, wherein the plasma treatment being performed simultaneously with and/or after the injection of the precursor based on the first species, the first species is based on a metal.

8. The method according to claim 7, wherein when the plasma is generated, the plasma treatment is free from dihydrogen injection.

9. The method according to claim 7, wherein the metal has an electronegativity between 1.1 and 2.4.

10. The method according to claim 7, wherein the first species comprises the metal and alkyl, amine, oxygenated or halogenated ligands.

11. The method according to claim 7, wherein the plasma treatment being performed simultaneously with the injection of the precursor based on the first species, the plasma treatment and the injection of said precursor are each performed by simultaneous or sequential pulses between the plasma treatment and the injection of said precursor.

12. The method according to claim 2, wherein, the plasma treatment being performed after the injection of the precursor based on the first species and/or after the injection of the precursor based on the second species, the first species is based on a metal and the second species comprises at least one among the elements oxygen, nitrogen and sulphur.

13. The method according to claim 12, the plasma treatment being performed simultaneously with the injection of the precursor based on the second species, the second species is chosen from the group consisting of O₂, N₂, NH₃, H₂S.

14. The method according to claim 12, the plasma treatment being performed after the injection of the precursor based on the second species, the second species is chosen from the group consisting of H₂O, O₂, NH₃.

15. The method according to claim 1, wherein the plate being configured to be adjusted in height in the reaction chamber, the method comprises an adjustment of the height of the plate prior to the plasma treatment.
